(19) United States
(12) Patent Application Publication
(10) Pub. No.: US 2014/0020937 A1
(43) Pub. Date: Jan. 23, 2014

(54) FABRICS WITH MULTI-LAYERED CIRCUIT AND MANUFACTURING METHOD THEREOF

(71) Applicant: KOREA ELECTRONICS TECHNOLOGY INSTITUTE, Seongnam-si (KR)

(72) Inventors: Young Hwan KIM, Yongin-si (KR); Hyuck Ki HONG, Yongin-si (KR); Dong Sun KIM, Seongnam-si (KR); Tae Ho HWANG, Seoul (KR); Jae Gi SON, Yongin-si (KR)

(21) Appl. No.: 13/918,401

(22) Filed: Jun. 14, 2013

(30) Foreign Application Priority Data
Jul. 19, 2012 (KR) 10-2012-0078851

(51) Int. Cl. H05K 1/02; H05K 3/10

(52) U.S. Cl. CPC H05K 1/0298; H05K 3/10
USPC 174/257; 427/97.3; 427/97.4; 174/261; 174/258; 174/262

(57) ABSTRACT

Fabrics with a multi-layered circuit of high reliability and a manufacturing method thereof are provided. The fabrics with the multi-layered circuit include: a base layer; a first conductive pattern which is formed on the base layer; a second conductive pattern which is formed to intersect with the first conductive pattern at least in part; and an insulating pattern which is formed on an intersection portion which is a region where the first conductive pattern and the second conductive pattern intersect.

### CROSS-REFERENCE TO RELATED APPLICATION

This application claims priority from Korean Patent Application No. 10-2012-0078851, filed on Jul. 19, 2012 in the Korean Intellectual Property Office, the disclosure of which is incorporated herein by reference in its entirety.

### BACKGROUND

1. Field

Methods and apparatuses consistent with exemplary embodiments relate to fabrics with a multi-layered circuit and a manufacturing method thereof, and more particularly, to fabrics with a multi-layered circuit of high reliability and a manufacturing method thereof.

2. Description of the Related Art

Modern clothing does not merely provide protection of human bodies but also provides a variety of functions. For example, the clothing that is used for users enjoying outdoor activities may be equipped with a temperature sensor or a humidity sensor therein, and may inform the user when a sensed temperature or humidity reaches a predetermined level, so that the user can adjust the temperature or humidity to an appropriate level.

In the case of the clothing equipped with such a sensor, a processor for processing data sensed by the sensor, a memory for storing the data, or a communication module for communicating with an external device should be attached to the clothing. These modules should be connected with one another through metal wiring. However, if many circuits should be independently provided in clothing like in a case in which many sensors are provided, it may be difficult to wire circuits in a limited area of the clothing.

Therefore, there is a demand for a method for effectively wiring circuits in a limited space area like clothing.

### SUMMARY

One or more exemplary embodiments may overcome the above disadvantages and other disadvantages not described above. However, it is understood that one or more exemplary embodiment are not required to overcome the disadvantages described above, and may not overcome any of the problems described above.

One or more exemplary embodiments provide fabrics with a multi-layered circuit of high reliability and a manufacturing method thereof.

According to an aspect of an exemplary embodiment, there is provided fabrics with a multi-layered circuit, the fabrics including: a base layer; a first conductive pattern which is formed on the base layer; a second conductive pattern which is formed to intersect with the first conductive pattern at least in part; and an insulating pattern which is formed on an intersection portion which is a region where the first conductive pattern and the second conductive pattern intersect.

The first conductive pattern and the second conductive pattern may include silver (Ag), and the insulating pattern may include silicone resin.

The insulating pattern may be formed to be wider than a width of the first conductive pattern and cover the first conductive pattern.

The first conductive pattern and the second conductive pattern may be electrically connected with each other, and the first conductive pattern and the second conductive pattern may be connected with each other through a via hole which is formed on the intersection portion to electrically connect the first conductive pattern and the second conductive pattern.

According to an aspect of another exemplary embodiment, there is provided a method for manufacturing fabrics with a multi-layered circuit, the method including: forming a first conductive pattern on a base layer; forming an insulating pattern on a predetermined region of the first conductive pattern; and forming a second conductive pattern on the insulating pattern to intersect with the first conductive pattern. The method may further include drying the insulating pattern after forming the insulating pattern.

If the fabrics with the multi-layered circuit according to the exemplary embodiments are used, wiring of various modules can be effectively configured in a limited space. Accordingly, circuits may be electrically separated or connected in a desired way in a simple process when the circuits are wired in fabrics, and functional fabrics of high reliability can be manufactured.

### BRIEF DESCRIPTION OF THE DRAWING FIGURES

The above and/or other aspects will be more apparent by describing in detail exemplary embodiments, with reference to the accompanying drawings, in which:

FIG. 1A is a perspective view of fabrics with a multi-layered circuit according to an exemplary embodiment;

FIG. 1B is a cross section view taken along line A-A′ of FIG. 1A;

FIG. 2 is a perspective view of fabrics with a multi-layered circuit according to another exemplary embodiment;

FIGS. 3A and 3B are cross section views of fabrics with a multi-layered circuit according to still another exemplary embodiment; and

FIGS. 4A to 4C are views to explain a method for manufacturing fabrics with a multi-layered circuit according to still another exemplary embodiment.

### DETAILED DESCRIPTION OF EXEMPLARY EMBODIMENTS

Exemplary embodiments will now be described more fully with reference to the accompanying drawings to clarify aspects, features and advantages of the inventive concept. The exemplary embodiments may, however, be embodied in many different forms and should not be construed as limited to the exemplary embodiments set forth herein. Rather, the exemplary embodiments are provided so that this disclosure will be thorough and complete, and will fully convey the scope of the application to those of ordinary skill in the art. In the accompanying drawings, an element having a specific pattern or a predetermined thickness may be illustrated, but this is to assist in an explanation or a distinction. Therefore, although an element having a specific pattern or a predetermined thickness is illustrated, the present disclosure should not be construed as limited to the feature of the illustrated element.

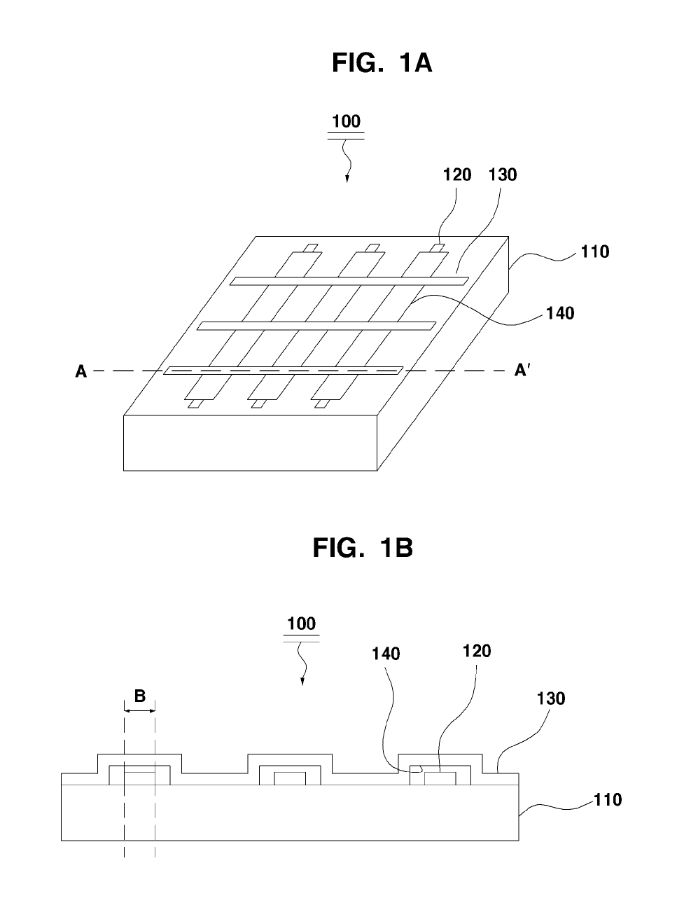

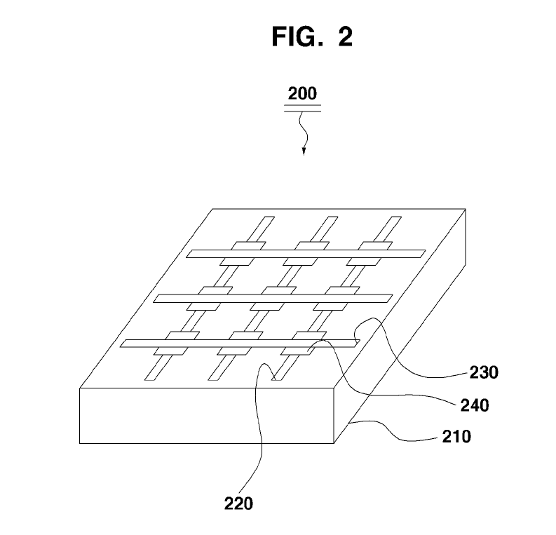

FIG. 1A is a perspective view of fabrics with a multi-layered circuit according to an exemplary embodiment, and FIG. 1B is a cross section view taken along line A-A′ of FIG. 1A. Fabrics 100 with a multi-layered circuit according to an exemplar embodiment include a base layer 110, a first conductive pattern 120 which is formed on the base layer 110, a second conductive pattern 130 which is formed to intersect with the first conductive pattern 120 at least in part, and an insulating pattern 140 which is formed on an intersection portion B where the first conductive pattern 120 and the second conductive pattern 130 intersect. In FIGS. 1A and 1B, the first conductive pattern, the second conductive pattern, and the insulating pattern are shown as having no thickness for the convenience of illustration.

The base layer 110 is a layer corresponding to a substrate on which conductive patterns are formed and may be fabrics in the exemplary embodiment. The fabrics are flexible and non-conductive due to their nature.

A multi-layered circuit may be formed on the base layer 110. The circuit may include two or more kinds of conductive patterns as shown in FIG. 1A. In particular, the circuit includes the first conductive pattern 120 and the second conductive pattern 130 which intersect with each other as shown in FIG. 1A, and accordingly, two or more conductive patterns may be formed on the base layer 110. In the accompanying drawings, a two-layered circuit including two kinds of conductive patterns is illustrated, but this is merely an example. An ordinary skilled person in the related art could easily apply the present disclosure to fabrics with a circuit including three or more layers.

The first conductive pattern 120 and the second conductive patter 130 intersect at least in part. In FIG. 1B, a region where the first conductive pattern 120 and the second conductive patter 130 intersect is shown as an intersection portion B.

In the case of a multi-layered circuit, two or more wiring patterns are included and thus there may be a region where wiring patterns vertically overlap each other like the intersection portion B. In particular, if the base layer 110 is fabrics that are used in clothing, a space where wiring patterns are to be formed is limited due to a limited area of the clothing and the characteristic of the clothing which is bendable according to a shape of a human body, and thus the intersection portion B is formed.

Since the intersection portion B is where two or more conductive patterns overlap each other, the intersection portion B may be formed by overlapping the conductive patterns each other if they need to overlap like signal lines. However, if the intersection portion B is a part of circuits constituting different modules, the conductive patterns should not overlap each other. Accordingly, the first conductive pattern 120 and the second conductive pattern 130 may need to be electrically separated from each other in the intersection portion B.

Accordingly, the insulating pattern 140 is formed on the intersection portion B where the first conductive pattern 120 and the second conductive pattern 130 intersect. In FIG. 1A, the insulating pattern 140 is formed to be wider than a width of the first conductive pattern 120 and cover the first conductive pattern 120, so that the first conductive pattern 120 is electrically insulated from the second conductive pattern 130. The insulating pattern 140 may not be formed at an end of the first conductive pattern 120. Accordingly, the first conductive pattern 120 may have its end, where the insulating pattern 140 is not formed, connected with other wiring patterns, modules or other parts such as a battery and wiring.

The first conductive pattern and the second conductive pattern may include material having good conductivity such as silver (Ag). The insulating pattern may use material having an electrically insulating property. However, if resin such as silicone resin is used for the insulating pattern, it is easy to print the silicone resin to cover a minute wiring pattern. The silicone resin may be printed on the base layer 110 and the conductive pattern may be formed on the printed silicone resin.

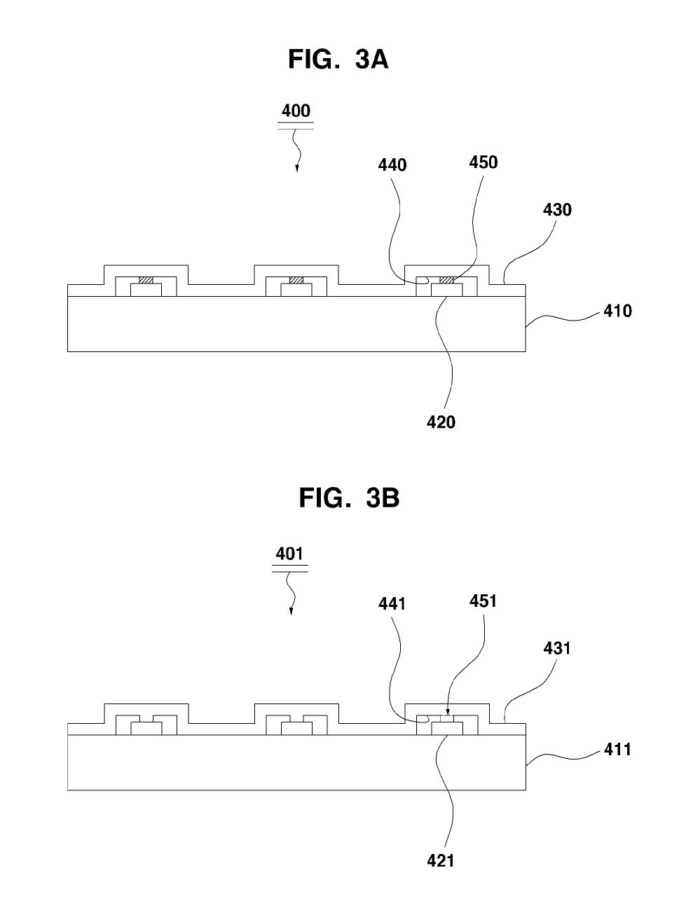

FIG. 2 is a perspective view of fabrics with a multi-layered circuit according to another exemplary embodiment. Fabrics 200 with a multi-layered circuit according to another exemplary embodiment includes a base layer 210, a first conductive pattern 220, a second conductive pattern 230, and an insulating pattern 240. Redundant explanations of the base layer 210, the first conductive pattern 220, the second conductive pattern 230, and the insulating pattern 240 in relation to FIG. 1 are omitted.

In FIG. 2, the insulating pattern 240 is formed on a region where the first conductive pattern 220 and the second conductive pattern 230 intersect. Unlike the insulating pattern 140 of FIG. 1 which covers the first conductive pattern except for the end of the first conductive pattern, the insulating pattern 240 of FIG. 2 is formed to cover the region where the first conductive pattern 220 and the second conductive patter 230 intersect. The insulating pattern 240 is formed on the first conductive pattern 220 corresponding to the region where the first conductive pattern 220 and the second conductive pattern 230 vertically intersect. Although the insulating pattern 240 may be formed to coincide with the region where the first conductive pattern 220 and the second conductive pattern 230 intersect, the insulating pattern 240 may be formed to be larger than the region where the first conductive pattern 220 and the second conductive pattern 230 intersect, considering easiness or reliability in a process. Accordingly, the insulating pattern 140 is formed to completely cover a side surface of the first conductive pattern 120 as shown in FIG. 1B, so that reliability of circuit wiring can be further improved.

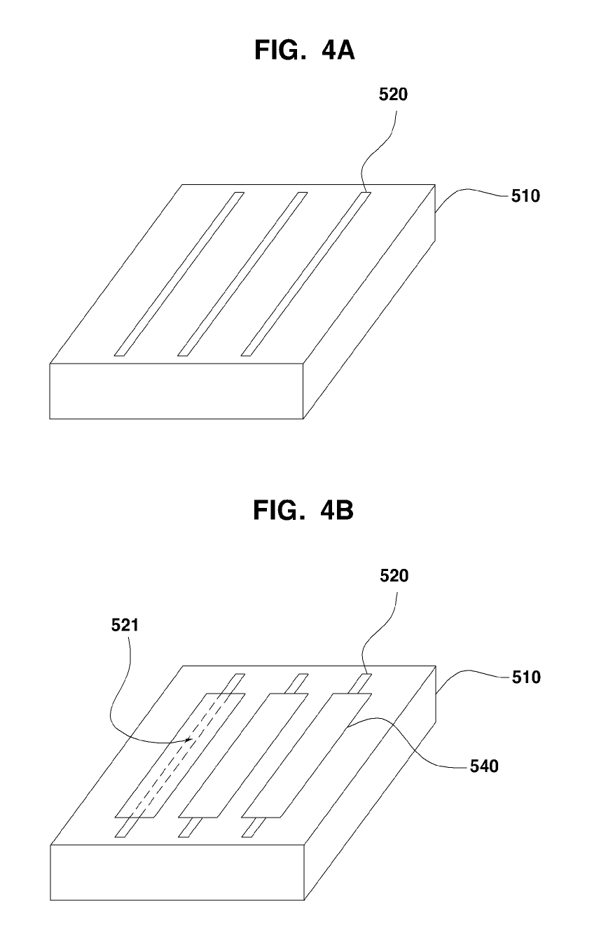

FIGS. 3A and 3B are cross section views of fabrics with a multi-layered circuit according to still another exemplary embodiment. Fabrics 400 and 401 with a multi-layered circuit in the present exemplary embodiment include base layers 410 and 411, first conductive patterns 420 and 421, second conductive patterns 430 and 431, and insulating patterns 440 and 441. Redundant explanations of the base layers 410 and 411, the first conductive patterns 420 and 421, the second conductive patterns 430 and 431, and the insulating patterns 440 and 441 in relation to FIG. 1 are omitted.

In FIG. 3A, the first conductive pattern 420 and the second conductive pattern 430 may be electrically connected with each other. The first conductive pattern 420 and the second conductive pattern 430 may be connected with each other through a via hole 450 which is formed on an intersection portion where the first conductive pattern 410 and the second conductive pattern 430 intersect.

The via hole 450 may be formed by filling a penetrating hole which is formed on the insulating pattern 440 with conductive material such as metal. The penetrating hole is formed by applying a mask to form the penetrating hole of the via hole 450 shape to the insulating pattern 440 when forming the insulating pattern 440 after forming the first conductive pattern 420. Unlike the via hole 450 of FIG. 3A, a via hole 451 of FIG. 3B may be formed by covering a penetrating hole formed on the insulating pattern 441 with the second conductive pattern 431. The via hole 450 of FIG. 3A may be formed by filling the penetrating hole with material different from that of the second conductive pattern 430 in a separate process when the via hole 450 needs to be formed of conductive material different from that of the second conductive pattern 430. The via hole 451 of FIG. 3B may be formed when it is preferable that the via hole 451 is formed of the same conductive material as that of the second conductive pattern 431, or when the insulating pattern 441 is not high and the via hole 451 does not cause a problem due to a difference in height even after the second conductive pattern 431 is formed.

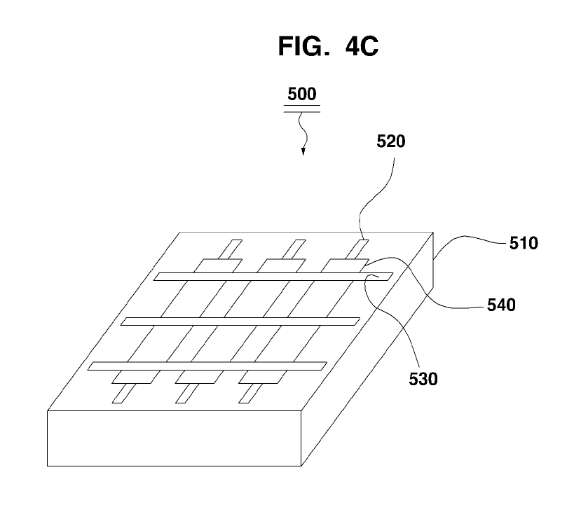

FIGS. 4A to 4C are views to explain a method for manufacturing fabrics with a multi-layered circuit according to still another exemplary embodiment.

According to the method for manufacturing the fabrics with the multi-layered circuit according to still another exemplary embodiment, a first conductive pattern 520 is formed on a base layer 510 first (see FIG. 4A). The conductive pattern may be formed by printing a conductive paste including conductive material on a desired region.

An insulating pattern 540 is formed on a predetermined region of the first conductive pattern 520, and is completely dried so that a second conductive pattern 530 is well formed on a top of the insulating pattern 540 (see FIG. 4B). The insulating pattern 540 is formed to cover a region 521 of the first conductive pattern 520 that is likely to intersect with the second conductive pattern 530. If the insulating pattern 540 is made of resin such as silicone resin, the insulating pattern 540 may be formed by forming a mask in a desired shape, printing the resin, and then removing the mask.

After that, the second conductive pattern 530 is formed on the top of the insulating pattern 540 so that the second conductive pattern 530 intersects with the first conductive pattern 520 formed under the insulating pattern 540. In this manner, the fabrics 500 with the multi-layered circuit are manufactured (see FIG. 4C).

The foregoing exemplary embodiments and advantages are merely exemplary and are not to be construed as limiting the present inventive concept. The exemplary embodiments can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. Fabrics with a multi-layered circuit, the fabrics comprising:
a base layer;
a first conductive pattern which is formed on the base layer;
a second conductive pattern which is formed to intersect with the first conductive pattern at least in part; and
an insulating pattern which is formed on an intersection portion which is a region where the first conductive pattern and the second conductive pattern intersect.

2. The fabrics as claimed in claim 1, wherein the first conductive pattern and the second conductive pattern comprise silver (Ag).

3. The fabrics as claimed in claim 1, wherein the insulating pattern comprises silicone resin.

4. The fabrics as claimed in claim 1, wherein the insulating pattern is formed to be wider than a width of the first conductive pattern and cover the first conductive pattern.

5. The fabrics as claimed in claim 1, wherein the first conductive pattern and the second conductive pattern are electrically connected with each other.

6. The fabrics as claimed in claim 5, further comprising a via hole which is formed on the intersection portion and electrically connects the first conductive pattern and the second conductive pattern.

7. A method for manufacturing fabrics with a multi-layered circuit, the method comprising:
forming a first conductive pattern on a base layer;
forming an insulating pattern on a predetermined region of the first conductive pattern; and
forming a second conductive pattern on the insulating pattern to intersect with the first conductive pattern.

8. The method as claimed in claim 7, further comprising drying the insulating pattern after forming the insulating pattern.
